(19) United States
(12) Patent Application Publication
(10) Pub. No.: US 2024/0364893 A1
(43) Pub. Date: Oct. 31, 2024

(54) TRANSMITTING SENSOR DATA IN DISTRIBUTED SENSOR NETWORKS

(71) Applicant: Robert Bosch GmbH, Stuttgart (DE)

(72) Inventors: Sergei Chubanov, Stuttgart (DE); Soheil Gherekhloo, Lauffen Am Neckar (DE)

(21) Appl. No.: 18/612,651

(22) Filed: Mar. 21, 2024

(30) Foreign Application Priority Data
Apr. 28, 2023 (EP) 23 17 0800.9

(51) Int. Cl. H04N 19/136; G06V 10/40; G06V 10/764; H04L 67/12; H04N 19/119

(52) U.S. Cl. CPC H04N 19/136; G06V 10/40; G06V 10/764; H04N 19/119; H04L 67/12

(57) ABSTRACT

Sensor data is encoded for transmission to a receiver by applying an object detection technique to the sensor data to detect an object in the sensor data and, to determine one or more attributes of the object, encoding the sensor data to obtain encoded sensor data. The encoding includes applying a data compression technique to the sensor data. The data compression technique is configurable by one or more compression parameters. The applying of the data compression technique to the sensor data includes selecting at least one of the compression parameters based on the attributes of the object, generating object data indicative of the attributes of the object, and sending the encoded sensor data and the object data to the receiver to enable the receiver to select one or more decompression parameters of a data decompression technique based on the one or more attributes of the object.

### CROSS REFERENCE

The present application claims the benefit under 35 U.S.C. § 119 of European Patent Application No. EP 23 17 0800.9 filed on Apr. 28, 2023, which is expressly incorporated herein by reference in its entirety.

### FIELD

The present invention relates to a computer-implemented method of encoding sensor data for transmission to a receiver. The present invention further relates to a sender device. The present invention further relates to a computer-implemented method of decoding sensor data received from a sender. The present invention further relates to a receiver device. The present invention further relates to a computer-readable medium comprising instructions for a processor system to perform any one of the computer-implemented methods, and to a distributed sensor network comprising the sender device and the receiver device.

### BACKGROUND INFORMATION

Distributed sensor networks are typically comprised of multiple, physically separated sensors that collect data from their environment. The acquired sensor data may be exchanged for further processing, which may be performed centrally in a single node of the sensor network or in a distributed manner across multiple nodes. Distributed sensor networks offer various advantages, such as an extended field of view and increased accuracy of perception, making them particularly beneficial for safety-critical applications like autonomous driving. Exchanging data between distributed nodes may require reliable communication, and in many cases, low latency.

Several approaches are available for the transmission of acquired sensor data from a sensor device to a receiver device, such as the aforementioned central processing node, such as raw-sensor-data sharing (RDS) and object-based sensor data sharing (ODS). In RDS, the sensor data captured by the sensors may be transmitted in its directly acquired form or after limited post-processing (e.g., demosaicing of camera data). The types of shared data may depend on the sensors used, such as delay-Doppler spectrum data for radar, point cloud data for lidar, and image data from cameras. RDS may provide the receiver device with access to (nearly) all the information acquired by the sensor, which in turn may allow the sensor data to be processed with high accuracy, e.g., to recognize and track objects. However, RDS may need high communication bandwidth to maintain low latency and high reliability, which may not always be satisfied by communication technology, particularly in dense sensor networks.

In ODS, objects and their attributes are first extracted by the sensor devices and then transmitted to other node(s). The interface for exchanging objects in ODS is typically domain specific. For instance, in automotive, the so-called collective perception message (CPM) is used in which objects together with their state vectors including the entities such as position, velocity, acceleration, etc., and the accuracy of the measurements are encoded. ODS may have the disadvantage that some useful data may be lost and cannot be considered by the receiver device. One example is an object which is not detectable in the sensor data of individual sensor devices, e.g., by there being insufficient information in the individual sensor data for such detection or the sensor device lacking the required computational performance. In such cases, the receiver device is also not able to detect the object, while with RDS, the receiver device may be able to detect the object in the received sensor data and act thereupon.

### SUMMARY

It would be desirable to provide methods and devices to address disadvantages of raw-sensor-data sharing (RDS) and object-based sensor data sharing (ODS).

In accordance with a first aspect of the present invention, a computer-implemented method and a corresponding sender device are provided for encoding sensor data for transmission to a receiver. In accordance with a further aspect of the present invention, a computer-implemented method and a corresponding receiver device are provided for decoding sensor data received from a sender. In accordance with a further aspect of the present invention, a computer-readable medium is provided. In accordance with a further aspect of the present invention, a distributed sensor network is provided comprising the sender device and the receiver device.

According to an example embodiment of the present invention, the above measures involve accessing sensor data which is captured by a sensor. The sensor data may for example be image data acquired by an image sensor, lidar data acquired by a lidar sensor, radar data acquired by a radar sensor, etc. The sensor data may pertain to a physical environment and the physical environment may include one or more objects. For example, captured image data may show a road which may include road users, such as cars, bicyclists, pedestrians, etc. Such and other types of objects may be detected in the sensor data using an object detection technique. Object detection techniques are conventional in various application areas and may, but do not need to, be, based on machine learning. As a result of applying the object detection technique to the sensor data, one or more objects may be detected in the sensor data. Typically, in addition to indicating that an object is present in the sensor data, the object detection technique may also determine one or more attributes of the object. Such attributes may for example include object characteristics such as a position and/or size of the object, but may also include the type of object which is detected, e.g., whether the detected object is a car or a bicycle or a pedestrian. The detection of the type of object may also be referred to as a classification, in which the types of objects may be represented by respective object classes, for example the class ‘car’ for cars, ‘bicycle’ for bicycles, ‘pedestrian’ for pedestrians, etc. Such object detection techniques are conventional.

According to an example embodiment of the present invention, the above measures further involve encoding the sensor data to obtain encoded sensor data and sending the encoded sensor data to a receiver. Such transmission of the encoded sensor data typically takes place via a communication channel. An example of a communication channel is a wired or wireless network. The encoding of the sensor data may comprise the use of a data compression technique to reduce the size of the sensor data. Such data compression is in general conventional. For example, U.S. Pat. No. 4,122,440 A describes an arithmetic coding scheme. Through a series of iterative steps, the algorithm generates a single number within a predefined range, representing the compressed data. It is said that this iterative approach allows for a compact representation of data.

In accordance with the above measures, the data compression technique which is used to compress the sensor data is configurable by one or more compression parameters. As such, the data compression technique may be reconfigured by the sender. Such reconfiguration may in general allow the data compression to be adapted, for example to the characteristics of the data to be compressed. In accordance with the above measures, and unlike U.S. Pat. No. 4,122,440 A, the one or more compression parameters to be used for the encoding of a particular instance of sensor data are selected based on the one or more attributes of the object which is detected in this instance of sensor data. This way, the data compression technique may be adapted to the object contained in the sensor data. For example, different compression parameters may be selected for different types, e.g., different classes, of objects. The one or more attributes of the object may additionally be encoded by the sender in the form of object data, which object data may be sent to the receiver together with the encoded sensor data, e.g., in a same data container or separately but linked to the encoded sensor data.

According to an example embodiment of the present invention, the receiver may use a data decompression technique when decoding the encoded sensor data. As in the case of the data compression technique used by the sender, the data decompression technique used by the receiver may be configurable by one or more decompression parameters. These data decompression parameters may, but do not need to, correspond in type to the configurable compression parameters. As the receiver is provided with the object data, the receiver may, when applying the data decompression technique to the encoded sensor data, select the decompression parameter(s) of the data decompression technique based on the one or more attributes of the object. This way, the receiver may correctly decode the encoded sensor data.

The above measures have the effect that the data compression is made adaptive to attributes of the object detected in the particular instance of sensor data to be encoded, e.g., to a particular camera image, lidar scan result, radar scan result, etc. This way, the data compression may be optimized for the particular instance of sensor data. Namely, the sensor data of different types of objects, or in general the sensor data of objects having different attributes, may differ in its characteristics and may be better compressed when data compression parameter(s) of the data compression technique are adapted to these object characteristics. To enable the receiver to correctly decode the encoded sensor data, the aforementioned object data is provided to receiver.

Advantageously, compared to ODS, the sensor data is provided to the receiver, which may avoid useful data from being lost and not being considered by the receiver. Compared to RDS, due to the object-adapted data compression, the transmitted data may be smaller in size and require less bandwidth to be transmitted. This way, a hybrid encoding scheme may be provided which may combine advantages of ODS and RDS.

The following optional aspects of the present invention may be described with reference to the encoding of the sensor data but will be understood by the skilled person to indicate technically corresponding optional aspects of the decoding of the sensor data.

Optionally, according to example embodiments of the present invention, applying the data compression technique to the sensor data comprises:
processing the sensor data to consecutively identify data patterns in the sensor data and convert each respective data pattern into a symbol selected from an auxiliary alphabet, thereby obtaining a string of symbols representing the sensor data;
encoding the string of symbols to obtain a binary representation of the string of symbols, wherein the encoding uses a decision pattern for decision-making in the encoding, wherein the decision pattern is selected based on the one or more attributes of the object, for example by selecting a different decision pattern for different values of an attribute of the object.

A particular instance of sensor data, which may for example be comprised of an array of real or complex numbers, may be converted into a string of symbols defined in an auxiliary alphabet. This way, two or higher dimensional data may be converted into a one dimensional string of symbols to be further encoded. This encoding, and typically any type of encoding of data, may involve decision-making. In accordance with the above measures, a decision pattern is used for the decision-making. As is conventional, a decision pattern may indicate one or more decision paths to be followed during the encoding to arrive at a decision for the encoding. In accordance with the above measures, the decision pattern may be selected based on the one or more attributes of the object. This selection of the decision pattern may be an example of the aforementioned selecting of one or more data compression parameters and may allow the decision pattern may be made adaptive to the characteristics of the object in the particular instance of sensor data. For example, the different decision pattern may be selected for different values of one or more attributes of the object.

According to an example embodiment of the present invention, optionally, encoding the string of symbols comprises using the decision pattern recursively for respective symbols. The decision pattern may be used recursively to encode consecutive symbols from the string of symbols.

According to an example embodiment of the present invention, optionally, encoding the string of symbols comprises generating a complex number to represent at least a substring of the string of symbols, wherein the decision pattern is representable as a set of areas in a 2D coordinate system, each area from the set of areas representing a different symbol from the auxiliary alphabet, wherein the complex number is selected by recursively:
selecting an area from the set of areas corresponding to a current symbol of the substring;
partitioning said selected area to obtain a set of subareas corresponding to an geometric arrangement of areas in the set of areas; and
selecting a subarea from the set of subareas corresponding to a next symbol of the substring;
wherein the complex number to represent the substring is selected based on a coordinate in the 2D coordinate system of a last subarea selected for a last symbol of the substring, for example based on a centroid of the last subarea; and
optionally, generating a binary representation of the complex number for transmission to the receiver.

The above measures define a graphical two-dimensional decision pattern which may be used recursively to select a complex number to represent a substring of the string of symbols, or in some embodiments to select a complex number to represent the entire string of symbols. This complex number may then be transmitted, for example in binary or in any other form, to the receiver. To determine the complex number, a set of areas may be provided in a 2D coordinate system, with each area corresponding to a different symbol from the auxiliary alphabet. A particular substring may then be converted into a complex number by selecting the area corresponding to a first symbol from the substring, then repartitioning the selected area to reestablish the set of areas as a set of subareas within the selected area, and then continuing the selection and repartitioning until arriving at a last symbol from the substring. This way, a last subarea may be selected for the last symbol of the substring, with the coordinates of the last subarea being used to determine the complex number. For example, a centroid of the last subarea may be used to determine the complex number, with the x-coordinate of the centroid determining the real part of the complex number and the y-coordinate of the centroid determining the imaginary part of the complex number. It may be advantageous to transmit the string of symbols as a complex number as the complex number may be selected in an interior of the last subarea in a way that achieves optimal data reduction, for example by selecting a complex number within the last subarea which has a minimum bit length of its binary representation in a given complex base. Nevertheless, the transmitted complex number may be decodable to the substring of symbols and therefore recoverable at the receiver. Namely, when decoding the encoded sensor data, a complex number may again be converted into a (sub) string of symbols by following the above-described process in reverse, e.g., by determining in which area from the set of areas the complex number falls and thereby determining a first symbol of the substring, then repartitioning the selected area to reestablish the set of areas as a set of subareas within the selected area, then determining in which subarea the complex number falls and thereby determining a next symbol, and then continuing the determining and repartitioning for a number of iterations to obtain the substring.

According to an example embodiment of the present invention, optionally, the computer-implemented method for encoding sensor data further comprises, and/or a processor subsystem of the sender device is further configured for:
determining a frequency of a respective data pattern in the sensor data to obtain a frequency of a corresponding symbol from the auxiliary alphabet; and
determining a relative size of each area in the set of areas based on the frequency, for example proportionally to the frequency.

According to an example embodiment of the present invention, optionally, the computer-implemented method for encoding sensor data further comprises, and/or a processor subsystem of the sender device is further configured for initially selecting a relative size of each area in the set of areas to be equal and adjusting the relative size during the encoding based on observed frequencies of respective data patterns.

According to an example embodiment of the present invention, optionally, the computer-implemented method for encoding sensor data further comprises, and/or a processor subsystem of the sender device is further configured for selecting the auxiliary alphabet using a machine learning technique, wherein the machine learning technique is trained to select respective symbols of the auxiliary alphabet so that a binary representation of the string of symbols has a minimum binary length in a complex base in which the binary representation of the complex number is generated.

According to an example embodiment of the present invention, optionally, the computer-implemented method for encoding sensor data further comprises, and/or a processor subsystem of the sender device is further configured for selecting a complex base in which a binary representation of the complex number is generated using a machine learning technique, wherein the machine learning technique is trained to select the complex base so that the binary representation of the complex number has a minimum binary length in the complex base.

According to an example embodiment of the present invention, optionally, the object detection technique is configured to detect and classify the object in the sensor data to obtain an object classification as an attribute of the object.

According to an example embodiment of the present invention, optionally, the sensor data comprises or is representable as a series or an array of complex numbers, for example in the form of a magnitude and a phase.

According to an example embodiment of the present invention, optionally, the sensor data comprises or is an array of sensor data elements, for example in the form of an image.

It will be appreciated by those skilled in the art that two or more of the above-mentioned embodiments, implementations, and/or optional aspects of the present invention may be combined in any way deemed useful.

Modifications and variations of any device, system, network, computer-implemented method and/or any computer readable medium, which correspond to the disclosed modifications and variations of another of such entities, can be carried out by a person skilled in the art on the basis of the present disclosure.

### BRIEF DESCRIPTION OF THE DRAWINGS

These and other aspects of the present invention will be apparent from and elucidated further with reference to the embodiments described by way of example in the following description and with reference to the figures.

FIG. 1 shows a hybrid sensor data compression scheme in which an object and one or more attributes of the object are detected in sensor data and in which the sensor data is encoded using a data compression scheme steered by the object attribute(s), according to an example embodiment of the present invention.

FIG. 2 shows an encoding graph which may be used in the encoding of the sensor data, according to an example embodiment of the present invention.

FIG. 3A illustrates how a static decision pattern may map coordinates in a 2D coordinate system to symbols of an auxiliary alphabet, wherein the static decision pattern partitions an area into a set of areas each representing a symbol from the auxiliary alphabet.

FIGS. 3B-3D illustrate how a point in the 2D coordinate system may be converted into a series of symbols and vice versa on the basis of a recursive partitioning of an area which comprises the point by the arrangement of areas defined by the static decision pattern.

FIG. 4 shows a data exchange between a sender device and a receiver device, according to an example embodiment of the present invention.

FIG. 5 shows a method of encoding sensor data for transmission to a receiver, according to an example embodiment of the present invention.

FIG. 6 shows a method of decoding sensor data received from a sender, according to an example embodiment of the present invention.

FIG. 7 shows a computer-readable medium comprising data, according to an example embodiment of the present invention.

It should be noted that the figures are purely diagrammatic and not drawn to scale. In the figures, elements which correspond to elements already described may have the same reference numerals.

### LIST OF REFERENCE NUMBERS AND ABBREVIATIONS

The following list of reference numbers is provided for facilitating the interpretation of the figures and shall not be construed as limiting the present invention.
50 communication channel
100 sender device
110 sensor
112 sensor data
114 delay [μs]
116 Doppler frequency [Hz]
120 sensor interface
140 processor subsystem
150 object detection function
152 detected object and object attributes (class)
154 object data
160 data compression function
180 communication interface
182 sensor data+object data
200 receiver device
220 communication interface
240 processor subsystem
300 set of areas representing static decision pattern
310 selected area
320 repartitioning of selected area
330 further repartitioning of further selected area
400 method of encoding sensor data for transmission to receiver
410 obtaining sensor data acquired by sensor
420 applying object detection technique to sensor data
430 encoding sensor data using data compression technique
440 generating object data
450 sending encoded sensor data and object data to receiver
500 method of decoding sensor data received from sender
510 receiving encoded sensor data from sender
520 receiving object data
530 decoding encoded sensor data based on object data
600 computer-readable medium (memory card)
610 stored data

### DETAILED DESCRIPTION OF EXAMPLE EMBODIMENTS

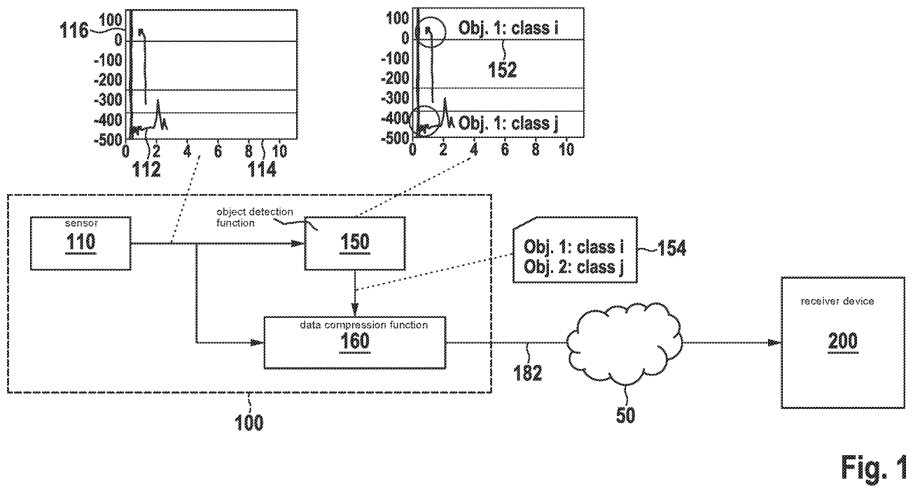

FIG. 1 shows a hybrid sensor data compression scheme in which a sender device 100 comprises or is connected to a sensor 110 to access sensor data acquired by the sensor. In the example of FIG. 1, the sensor data is radar data 112 which may be visualized as an image having on one axis the delay [μs] 114 and on the other axis the Doppler frequency [Hz] 116. The sender device 100 may be configured to apply an object detection technique to the sensor data 112 to detect one or more objects in the sensor data, which is shown in FIG. 1 by an object detection function 150 detecting two objects 152 and one or more attributes of the objects. In this and other examples, an object attribute may be an object class, e.g., as obtained from a classification of the object, being in this example class i for object 1 and class j for object 2. The object detection function 150 may generate object data 154 which is indicative of the objects and their attribute(s), being in this example the object class. Such object data may take any suitable form, including XML, json, a binary format, etc. Both the sensor data 112 and the object data 154 may be input into a data compression function 160 which may compress the sensor data 112 using the object data 154. In particular, the data compression technique used by the data compression function 160 may configurable by one or more compression parameters, and the object attribute(s), being in this example the object class, may determine the value of the one or more compression parameters. As a result, encoded sensor data may be obtained which may be provided together with the object data as data 182 to a receiver device, e.g., via a communication channel 50.

The following describes a specific example of the encoding of the sensor data. In this specific example, the sensor data is assumed to be complex data, such as the aforementioned radar data in which, for each delay and Doppler frequency instant, a complex number describes the attenuation and phase of the channel. However, this is not a limitation, in that the sensor data may also be comprised of real numbers.

One may consider the sensor data to represent or be representable as a matrix M of complex numbers whose real and imaginary parts are integers ranging from 0 to u. Such a matrix may for example represent an image or any other instance of sensor data. For each matrix, object detection may be used to determine the classes of objects represented in the matrix. One may assume that there are in general c classes enumerated by indices in [c]={1, . . . , c}. The presence of a class of objects in M may be encoded by a binary vector b ∈{0,1}^{c} whose Ith component is 1 when M contains an object of the Ith class. If nothing is known about the object classes represented in M, or if such object classes are simply not present in M, then the respective binary vector may be zero. It is noted that the information about object classes may also be available in the form of a probability distribution over [c]. In this case, one may draw an index l for each object from the respective distribution. The obtained set of class indices, one per object, may then be used to construct the mentioned binary vector b.

When encoding a respective instance of sensor data, and thus M, a goal may be to represent M with a minimum possible number of binary digits, which number may preferably be smaller than the initial size of the sensor data to be encoded. The following provides a specific example of an encoding of M and a subsequent decoding. In this example, a different decision pattern is selected for the encoding and decoding depending on the object class of the detected object. It will be appreciated, however, that also other compression parameter(s) may be selected based on other object attributes as this may equally establish an object-adaptive encoding of the sensor data.

Let vect(M) be the complex vector enumerating the entries of M in a column-wise manner. Each entry of M may be represented in the form Σⱼ₌₀^{|log}^{₂}^{u|}2^{j}qⱼ where qⱼ belong to Q=┌0,1, i, 1+i┐. Therefore, vect(M) may be represented as a Q-vector that may be denoted by vect_{Q}(M) and which may be partitioned in fixed-size series, of symbols of Q, each comprising ┌log₂u┐ components representing the respective component of vect(M). The Q-vector representing M may contain repeated patterns which may be recognized and encoded as respective symbols of an auxiliary alphabet E.

The auxiliary alphabet Σ may be chosen in various ways. One may generally assume that Q⊆Σ. (For the initial choice of Σ, one can also include series q . . . q, for each q∈Q, whose lengths are powers of 2, up to a given length not greater than the dimension of vect(M).) One may further assume, without loss of generality, that all input matrices are of the same size, which means that the number n of symbols of Q in vect_{Q}(M) may be fixed. In examples in which different instances of sensor data may have different matrix shapes, an additional symbol “ED” may be introduced having the meaning “end of data”. In such examples, each encoding string may end with “ED”, which can be used by the encoder to determine when to stop.

Each of the n positions of a Q vector with n components may be associated with a weight. For position j, the weight may be computed as 2^{jmod┌log}^{₂}^{u┐}. Let the respective weight be denoted by ωⱼ. Let x be a string over Σ representing z′ΣQⁿ. By the weighted error with which x represents another z∈Qⁿ the following may be meant: the sum of weights of the components in which z′ differs from z divided by the total weight of components of a vector in Qⁿ. Let z_{k,t} denote (zₖ, . . . , zₜ). The weighted error with which z_{k,t} may be represented by a symbol α∈Σ is the sum of the weights in {ωᵢ:i∈{k, . . . , t}, z_{k,t}[i]≠zₐ[i−k+1[}, where zₐ ∈Q^{t-k+1} is the Q-vector represented by a.

Let A be an algorithm representing vect_{Q}(M) as a string over Σ with a given admissible weighted error. Algorithm A may be a greedy algorithm which chooses a suitable symbol in Σ with the maximum length at each iteration. An example of algorithm A may be the following:

Input: z = vect_{Q}(M) and ρ ≥ 0 (admissible error rate, may be
zero)
Output: String x over Σ representing z.
k: = 1, e: = 0, let x be an empty string.
while k is not greater than the length of z do
Choose z_{k,t} with maximum t − k such that z_{k,t} is represented
by a symbol a ∈ Σ with the weighted error not greater than
the total weight of z times ρ minus e.
Increase e by the weighted error with which a represents
z_{k,t}. Write a to the end of x.
k: = t + 1
end while
Return x.

The sensor data may be encoded by an encoder using algorithm A to construct a string x representing input matrix M.

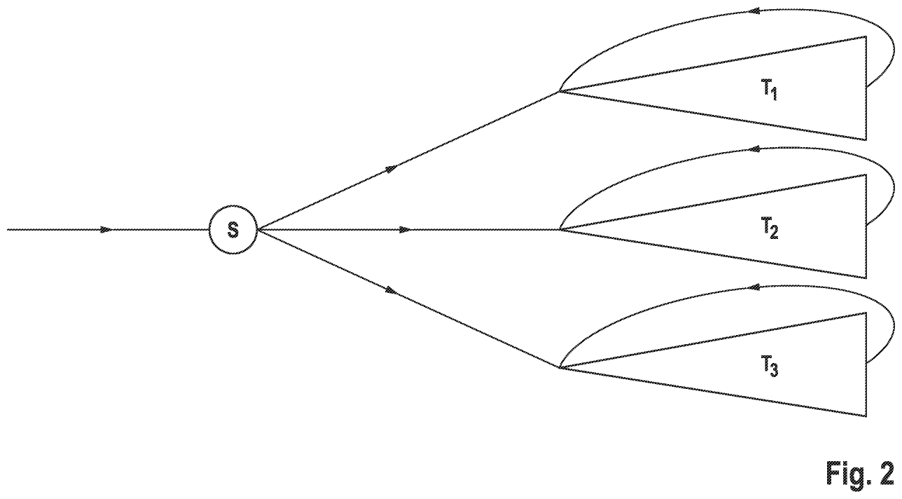

Mathematically speaking, the encoder may be represented as a finite-state machine represented in the form of a directed graph, which graph is also shown in FIG. 2 and which may comprise the following components:
A collection of decision trees T₁, . . . , Tₖ, one for each index i∈[m], each tree being described by a decision pattern DPᵢ.
A node s which may be connected with each Tᵢ by an arc (s,r(Tᵢ)).
A mapping φ: {0,1}^{c}→[m] associated with s.
For each Tᵢ: Arcs connecting the leaves of Tᵢ with its root r(Tᵢ).
For each Tᵢ: Each node v≠r(Tᵢ) may be labeled by a∈Σ. This label may be denoted by a(v).
For each Tᵢ: For each node v there may be an associated family of decision sets S(v,a)⊂[−1,1]², a Σ2:
   If v is not the root and w is its parent node, then U_{a∈Σ}S(v,a)=S (w,a(v)).

$${⋃}_{a ∈ \sum } S ( r ( {T}_{i} ) , a ) = {[ - 1 , 1 ]}^{2} .$$

A leaf of Tᵢ may be a node l such that a further application of the respective decision pattern would lead to a child v of l such that the smallest side of S(v,a) is smaller than Δ for some a∈Σ, where Δ may be a hyper-parameter, for example chosen by the user or predetermined.

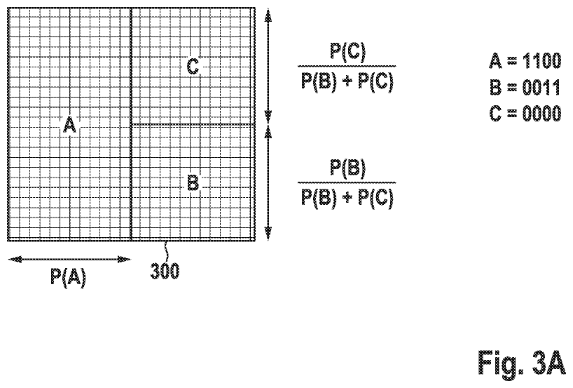

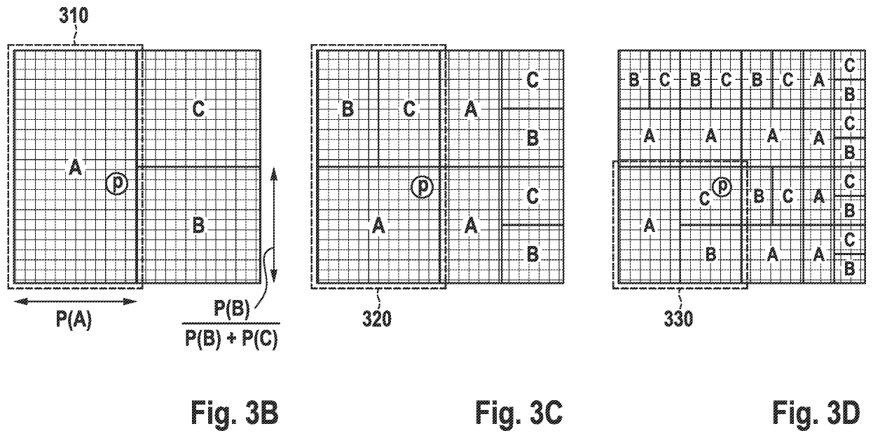

FIG. 3A illustrates how a static decision pattern may map coordinates in a 2D coordinate system to symbols of an auxiliary alphabet. The static decision pattern may be a rule or an algorithm prescribing how to partition an area into a set of areas with each area from the set representing a different symbol from the auxiliary alphabet. In this static decision pattern, the following frequencies of occurrences are assumed: P(A)=½, P(B)=¼, and P(C)=¼ of symbols A,B, and C of Σ. The size of each area may be selected proportionally to the frequency of occurrence.

FIGS. 3B-3D illustrate how a point in the 2D coordinate system may be converted into a series of symbols and vice versa on the basis of a recursive partitioning of areas. In other words, the decision pattern of FIG. 3A may be used for branching in a decision tree. It can be seen that the areas associated with symbols contain a smaller number of lattice points at the next level. Point p may encode string AAC. Point p may be represented as a complex number z(p) and sent to the receiver.

Below a dynamic decision pattern is described in which the decision pattern takes decisions using a probability distribution Pᵥ associated with a given node. The following may represent a recursive application of the decision pattern DPᵢ to a given node:

Input : Node v.
Output: S(v,a), ∀a ∈ Σ.
Let R = [−1,1]² if v = r(Tᵢ). Otherwise, let R = S(w,a(v) where
w is the parent node of v.
Σ′: = Ø, [symbol] : = {R}, Σ_{R}: = Σ.
while There exists R′ ∈ [symbol] with |Σ_{R′}| > 1 do
Put Pᵥ(a), a ∈ Σ_{R}′, in the decreasing order: p₁ ≥ p₂ ≥ . . . ≥ pₜ.
ξ: = (p₁ + . . . + p_{└t/2┘})/(p₁ + . . . + pₜ)
Choose a side of R′ of the maximum length.
Divide R′ by the line segment perpendicular to the
mentioned side such that R′ is decomposed into two
rectangles R₁ and R₂ with areas ξ and 1 − ξ, respectively.
Let Σ_{R}_{₁}be the part of Σ_{R}′ corresponding to p₁ . . . , p_{└t/2┘}. Σ_{R}_{₂}: =
Σ_{R}′\Σ_{R}_{₁}′
Replace R′ by R₁ and R₂ in collection [symbol] .
end while
for R′ ∈ [symbol] do
Set S(v,a): = R′, where a is such that Σ_{R}′ = {a}.
end for
Return the sets S(v,a).

The above procedure may decompose R into rectangles, being an example of the aforementioned areas, associated with the symbols of Σ. The areas of the rectangles relatively to the area of R may in some examples be exactly proportional to the respective probabilities Pᵥ(a), a∈Σ. The dynamic choice of Pᵥ may allow one to take into account complex dependencies of probabilities of observing a given symbol of the previously observed combinations of symbols in the same string representing M. Since Pᵥ depends on v, Pᵥ may also depend on the class i associated with Tᵢ, containing v.

The encoder may encode M as a sequence of complex numbers and represent them as a binary string in a given complex base admitting a binary representation:

Input: b ∈ {0,1}^{c} and complex matrix M.
Output: y being a vector of complex numbers encoding M
and its binary representation in a given complex base.
Use algorithm A to represent M as a string x over Σ.
Compute i = φ(b).
Let v = r(Tᵢ). This is the current node.
k: = 1. This is the index of the current symbol in x.
while k is less than the length of x do
w: = v
Let v be the child node of w with a(v) = xₖ.
if v is a leaf of Tᵢ then
Set v: = r(Tᵢ). (Go back to the root of Tᵢ.)
Choose p in the interior of S(v,xₖ) having the minimum bit
length of its binary representation in a given complex
base (e.g., i − 1 (see for example Walter Penney. 1965. A
“Binary” System for Complex Numbers. J. ACM 12, 2 (April
1965), 247-248. https://doi.org/10.1145/321264.321274)
and write its complex representation to the end of y.
end if
k: = k + 1
end while
if v is not a leaf of Tᵢ then
Choose p in the interior of S(v,xₖ) having the minimum bit
length of its binary representation in a given complex
base and write its complex representation to the end of
y.
end if
Return the complex vector y, the binary representations of
its components and their binary lengths.

The decoder may reconstruct the sensor data which may be received in encoded form, namely in form of a sequence of complex numbers or their binary representations (with known binary lengths of components and the complex base in which they have been encoded) as follows:

Input: b ∈ {0,1}^{c}, n, and y given as a complex vector or its
binary representation.
Output: The matrix M encoded by y.
Choose i = φ(b).
Let v = r(Tᵢ). This is the current node.
k: = 1 (This is the index of the current complex number in
y.)
r: = 0 (This is the counter of the number of symbols of Q
discovered by the current iteration.)
Let x be an empty string.
while a(v) ≠ “ED” and r < n do
if v ≠ r(Tᵢ) then
Write a(v) to the end of x.
r: = r + size_{Q}(a(v)) where size_{Q}(a(v)) is the number of symbols
of Q represented by a(v).
end if
w: = v
Set v to the child node of w, labeled with a(v), such that
yₖ ∈ S(v,a(v)).
if v is a leaf of Tᵢ then
Set v: = r(Tᵢ). (Go back to the root of Tᵢ.)
k: = k + 1
end if
end while
If “ED” is contained in Σ, write “ED” to the end of x.
To obtain vect_{Q}(M), first replace the components of x by
the respective series of symbols of Q.
Then construct vect_{Q}(M) by partitioning vect_{Q}(M) in series
of ┌log₂u┐ symbols of Q. After that, represent each entry
of M as the respective expansion.
Return M.

A coding system S_{θ} may be configured by θ describing the coding scheme: θ consists of the lattice L, the decision patterns associated with the trees and their nodes, the mapping φ associated with node s, and the auxiliary alphabet Σ. Let Σ₀ be an initial auxiliary alphabet (it contains Q and may, e.g., include series q . . . q, for each q∈Q, whose lengths are powers of 2, up to a given length not greater than the dimension of vect(M)). Let [symbol] consist of all alphabets each of which can be obtained from Σ₀ by modifying Q-vectors represented by symbols of Σ₀. For instance, if a component of a Q-vector of the form q . . . q is to be modified to q′, q is to be changed to q′ at the respective position of that Q-vector. Let [symbol] be the family of all alphabets containing Q as a subset and being subsets of alphabets in [symbol] . The problem of finding an optimal alphabet can be formulated as the following optimization problem:

$${min}_{\sum ∈ 𝒜} \frac{1}{\vert D \vert} {\sum }_{M ∈ D} f ∘ {S}_{θ ( \sum )} ( M ) ,$$

where D is a training set and f is the total binary length of M∈D in a given complex base when using S_{θ}. Here, the notation θ(Σ) means a configuration which is chosen based on alphabet Σ with all other parameters such as the A and decision patterns being fixed.

To start with the straightforward binary representation of vect_{Q}(M), one may choose alphabet Σ₀=Q as the initial solution and a decision pattern determined by equal probabilities for all symbols. The Δ can be chosen as Δ=2/u. Remark: By choosing a sufficiently small Δ one may encode M as a single complex number. Moreover, if the sender and receiver are analog devices exchanging signals that can be interpreted as sequences of complex numbers, the vector y may be transmitted directly. In this case Δ may be selected to correspond to the accuracy with which the devices are able to measure, transmit, and receive such complex numbers.

For solving the above optimization problem, taking into account that alphabets of [symbol] can be interpreted as binary vectors, any suitable black-box optimization method for binary optimization may be used.

It is noted that function φ can be a binary decision diagram whose input would be b and the output be a unit vector whose nonzero component would correspond to i.

Initially, probability distributions Pᵥ can all be equal (e.g., to a probability distribution representing empirical probabilities of symbols of the respective alphabet E), in which case we are talking about a static decision pattern for each i. By means of black-box optimization and machine-learning techniques, more suitable Pᵥ's may be learned as functions depending on i and sequences of symbols observed when going from the root of Tᵢ to v.

Note that one may also optimize with respect to the complex base in which binary representations of complex numbers are computed in the output of the encoder.

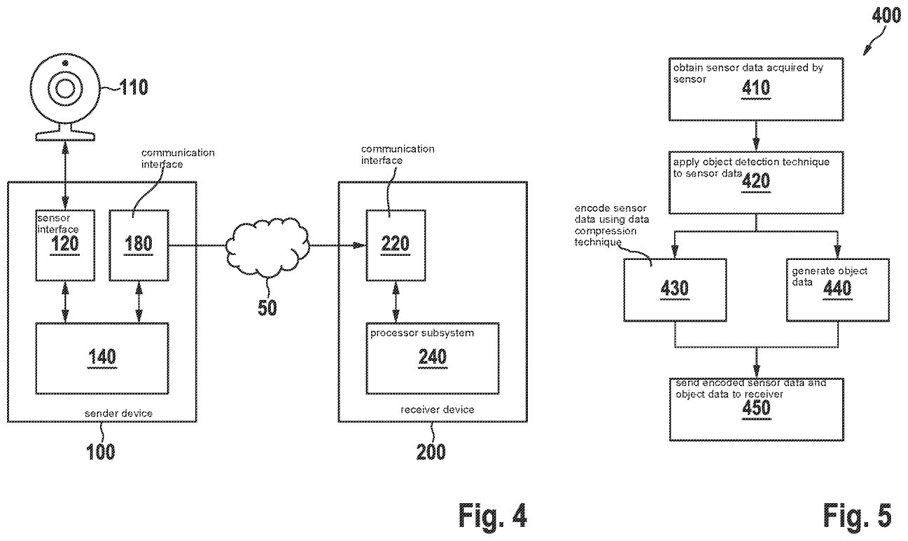

FIG. 4 shows a data exchange between a sender device 100 and a receiver device 200. The sender device 100 may be configured to encode sensor data for transmission to the receiver device 200, or to any other receiver. To obtain access to the sensor data, the sender device 100 may comprise a sensor interface 120 to a sensor 110. By way of example, the sensor 110 is shown in FIG. 4 in the form of an external camera 110. Alternatively, the sensor 110 may be an internal, e.g., built-in, component of the sender device 100, such as a built-in camera. Moreover, alternatively or in addition to a camera, the sensor 110 may comprise any other type of sensor, such as an ultrasound sensor, lidar sensor, radar sensor, microphone, etc. The sensor interface 120 may be a type of sensor interface which corresponds to the type of sensor 110. For example, for the example of the sensor being a camera, the sensor interface may be a camera interface, etc. In general, the sensor interface 120 may be a bus-type of interface, such as an USB interface, or a serial interface, such as a CSI interface, or a network interface, such as a wireless network interface based on Wi-Fi, Bluetooth, Zigbee, Matter, etc., or an application specific interface such as a MIPI interface for automotive applications, etc.

The sender device 100 may further comprise a processor subsystem 140 which may be configured to provide the functionality as described in this specification with respect to the encoding of the sensor data for transmission to a receiver. For that purpose, although not shown in FIG. 4, the sender device 100 may comprise a memory comprising corresponding computer-readable instructions for the processor subsystem.

The sender device 100 may further comprise a communication interface 180 to the receiver device 200. Using the communication interface 180, the sender device 100 may provide the encoded sensor data and the object data as described elsewhere in this specification to the receiver device 200, for example via a communication channel 50. In one example, the communication interface 180 may be a network interface, such as a wired network interface based on Ethernet or optical communication or a wireless network interface based on Wi-Fi_33, Bluetooth, Zigbee, Matter, etc. Another example is that the communication interface 180 may be a bus-type of interface or a serial interface or an application specific interface, for example of the types as described above for the sensor interface 120.

In some examples, the sender device 100 may be a sensor device in that the sender device may comprise the sensor and limited processing means enabling the sensor to generate and send the encoded sensor data to the receiver device 200. In a specific example, the sender device 100 may be a node in a distributed sensor network. In another specific example, the sender device 100 may be an automotive sensor device and the object data may be a collective perception message (CPM). Another specific example is that the sender device 100 may be an Internet-of-Things (IoT) device.

FIG. 4 further shows a receiver device 200 which is shown to comprise a communication interface 220 of a type as described with reference to the communication interface 180 of the sender device 100. The receiver device 200 may further comprise a processor subsystem 240 which may be configured to provide the functionality as described in this specification with respect to the decoding of the sensor data received from the sender device 100. For that purpose, although not shown in FIG. 4, the receiver device 200 may comprise a memory comprising computer-readable instructions for the processor subsystem 240. The receiver device 200 may for example be a central processing node of a distributed sensor network. In a specific example, the receiver device 200 may be an automotive processing unit. Another specific example is that the receiver device 200 may be a server or host computer. In some examples, the receiver device 200 may be a same type of device as the sender device 100, e.g., in applications in which the processing of the sensor data is distributed amongst devices.

With further reference to the processor subsystems 140, 240 of the sender device and the receiver device, each of these may be embodied by a single CPU, such as a x86 or ARM-based CPU, but also by a combination of such CPUs and/or other types of processing units, such as GPUs.

In general, each entity described in this specification may be embodied as, or in, a device or apparatus. The device or apparatus may comprise one or more (micro) processors which execute appropriate software. The processor(s) of a respective entity may be embodied by one or more of these (micro) processors. Software implementing the functionality of a respective entity may have been downloaded and/or stored in a corresponding memory or memories, e.g., in volatile memory such as RAM or in non-volatile memory such as Flash. Alternatively, the processor(s) of a respective entity may be implemented in the device or apparatus in the form of programmable logic, e.g., as a Field-Programmable Gate Array (FPGA). Any input and/or output interfaces may be implemented by respective interfaces of the device or apparatus. Each functional unit of a respective entity may be implemented in the form of a circuit or circuitry. A respective entity may also be implemented in a distributed manner, e.g., involving different devices or apparatus.

FIG. 5 shows a method 400 of encoding sensor data for transmission to a receiver. The method 400 may correspond to an operation of the sender device as described elsewhere in this specification. However, this is not a limitation, in that the method 400 may also be performed using another system, apparatus or device.

The method 400 may comprise, in a step titled “OBTAINING SENSOR DATA ACQUIRED BY SENSOR”, obtaining 410 sensor data acquired by a sensor. The method 400 may further comprise, in a step titled “APPLYING OBJECT DETECTION TECHNIQUE TO SENSOR DATA”, applying 420 an object detection technique to the sensor data to detect an object in the sensor data and to determine one or more attributes of the object. The method 400 may further comprise, in a step titled “ENCODING SENSOR DATA USING DATA COMPRESSION TECHNIQUE”, encoding 430 the sensor data to obtain encoded sensor data, wherein the encoding comprises applying a data compression technique to the sensor data, wherein the data compression technique is configurable by one or more compression parameters, wherein applying the data compression technique to the sensor data comprises selecting at least one of the one or more compression parameters based on the one or more attributes of the object. The method 400 may further comprise, in a step titled “GENERATING OBJECT DATA”, generating 440 object data indicative of the one or more attributes of the object. The method 400 may further comprise, in a step titled “SENDING ENCODED SENSOR DATA AND OBJECT DATA TO RECEIVER”, sending 450 the encoded sensor data and the object data to the receiver to enable the receiver to select one or more decompression parameters of a data decompression technique based on the one or more attributes of the object.

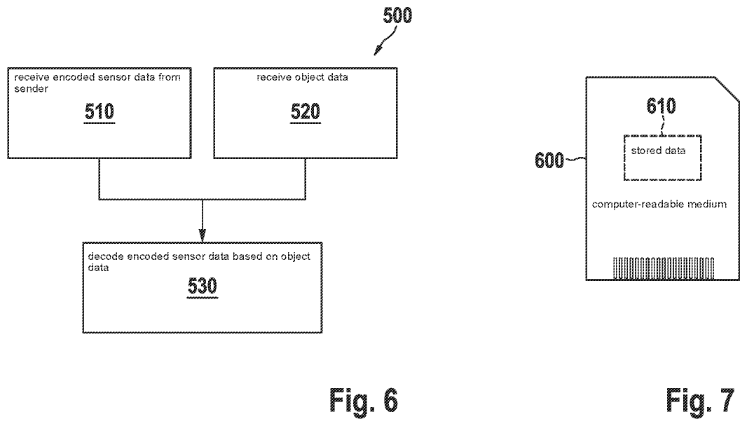

FIG. 6 shows a method 500 of decoding sensor data received from a sender. The method 500 may correspond to an operation of the receiver device as described elsewhere in this specification. However, this is not a limitation, in that the method 500 may also be performed using another system, apparatus or device.

The method 500 may comprise, in a step titled “RECEIVING ENCODED SENSOR DATA FROM SENDER”, receiving 510 encoded sensor data from the sender. The method 500 may further comprise, in a step titled “RECEIVING OBJECT DATA”, receiving 520 object data from the sender, wherein the object data is indicative of one or more attributes of an object which is detectable in the sensor data. The method 500 may further comprise, in a step titled “DECODING ENCODED SENSOR DATA BASED ON OBJECT DATA”, decoding 530 the encoded sensor data to obtain decoded sensor data, wherein the decoding comprises applying a data decompression technique to the encoded sensor data, wherein the data decompression technique is configurable by one or more decompression parameters, wherein applying the data decompression technique to the encoded sensor data comprises selecting at least one of the one or more decompression parameters based on the one or more attributes of the object.

It will be appreciated that, in general, the steps of the method 400 of FIG. 5 and those of the method 500 of FIG. 6 may be performed in any suitable order, e.g., consecutively, simultaneously, or a combination thereof, subject to, where applicable, a particular order being necessitated, e.g., by input/output relations.

The method(s) may be implemented on a computer as a computer implemented method, as dedicated hardware, or as a combination of both. As also illustrated in FIG. 7, instructions for the computer, e.g., executable code, may be stored on a computer-readable medium 600, e.g., in the form of a series 610 of machine-readable physical marks and/or as a series of elements having different electrical, e.g., magnetic, or optical properties or values. The computer-readable medium 600 may be transitory or non-transitory. Examples of computer-readable mediums include memory devices, optical storage devices, integrated circuits, etc. FIG. 7 shows a memory card 600.

Examples, embodiments or optional features, whether indicated as non-limiting or not, are not to be understood as limiting the present invention.

It should be noted that the above-mentioned embodiments illustrate rather than limit the present invention, and that those skilled in the art will be able to design many alternative embodiments without departing from the scope of the present invention. Any reference signs placed between parentheses shall not be construed as limiting. Use of the verb “comprise” and its conjugations does not exclude the presence of elements or stages other than those stated. The article “a” or “an” preceding an element does not exclude the presence of a plurality of such elements. Expressions such as “at least one of” when preceding a list or group of elements represent a selection of all or of any subset of elements from the list or group. For example, the expression, “at least one of A, B, and C” should be understood as including only A, only B, only C, both A and B, both A and C, both B and C, or all of A, B, and C. The present invention may be implemented by means of hardware comprising several distinct elements, and by means of a suitably programmed computer. In the device describes as including several means, several of these means may be embodied by one and the same item of hardware. The mere fact that certain measures are recited in different embodiments does not indicate that a combination of these measures cannot be used to advantage.

What is claimed is:

1. A computer-implemented method of encoding sensor data for transmission to a receiver, comprising the following steps:
obtaining sensor data acquired by a sensor;
applying an object detection technique to the sensor data to detect an object in the sensor data and to determine one or more attributes of the object;
encoding the sensor data to obtain encoded sensor data, wherein the encoding includes applying a data compression technique to the sensor data, wherein the data compression technique is configurable by one or more compression parameters, wherein the applying of the data compression technique to the sensor data includes selecting at least one of the one or more compression parameters based on the one or more attributes of the object;
generating object data indicative of the one or more attributes of the object; and
sending the encoded sensor data and the object data to the receiver to enable the receiver to select one or more decompression parameters of a data decompression technique based on the one or more attributes of the object.

2. The method according to claim 1, wherein the applying of the data compression technique to the sensor data includes:
processing the sensor data to consecutively identify data patterns in the sensor data and convert each respective data pattern into a symbol selected from an auxiliary alphabet, thereby obtaining a string of symbols representing the sensor data;
encoding the string of symbols to obtain a binary representation of the string of symbols, wherein the encoding uses a decision pattern for decision-making in the encoding, wherein the decision pattern is selected based on the one or more attributes of the object, by selecting a different decision pattern for different values of each attribute of the object.

3. The method according to claim 2, wherein the encoding of the string of symbols includes using the decision pattern recursively for respective symbols.

4. The method according to claim 3, wherein the encoding of the string of symbols includes generating a complex number to represent at least a substring of the string of symbols, wherein the decision pattern is representable as a set of areas in a 2D coordinate system, each area from the set of areas representing a different symbol from the auxiliary alphabet, wherein the complex number is selected by recursively:
selecting an area from the set of areas corresponding to a current symbol of the substring;
partitioning the selected area to obtain a set of subareas corresponding to an geometric arrangement of areas in the set of areas; and
selecting a subarea from the set of subareas corresponding to a next symbol of the substring;
wherein the complex number to represent the substring is selected based on a coordinate in the 2D coordinate system of a last subarea selected for a last symbol of the substring.

5. The method according to claim 4, further comprising:
generating a binary representation of the complex number for transmission to the receiver.

6. The method according to claim 4, further comprising:
determining a frequency of each respective data pattern in the sensor data to obtain a frequency of a corresponding symbol from the auxiliary alphabet; and
determining a relative size of each area in the set of areas based on the frequency.

7. The method according to claim 6, further comprising initially selecting a relative size of each area in the set of areas to be equal and adjusting the relative size during the encoding based on observed frequencies of respective data patterns.

8. The method according to claim 4, further comprising:
selecting the auxiliary alphabet using a machine learning technique, wherein the machine learning technique is trained to select respective symbols of the auxiliary alphabet so that a binary representation of the string of symbols has a minimum binary length in a complex base in which the binary representation of the complex number is generated.

9. The method according to claim 4, further comprising:
selecting a complex base in which a binary representation of the complex number is generated using a machine learning technique, wherein the machine learning technique is trained to select the complex base so that the binary representation of the complex number has a minimum binary length in the complex base.

10. The method according to claim 1, wherein the object detection technique is configured to detect and classify the object in the sensor data to obtain an object classification as an attribute of the object.

11. The method according to claim 1, wherein the sensor data includes or is representable as a series or an array of complex numbers, in a form of a magnitude and a phase.

12. The method according to claim 1, wherein the sensor data includes or is an array of sensor data elements, in a form of an image.

13. A computer-implemented method of decoding sensor data received from a sender, the method comprising the following steps:
receiving encoded sensor data from the sender;
receiving object data from the sender, wherein the object data is indicative of one or more attributes of an object which is detectable in the sensor data; and
decoding the encoded sensor data to obtain decoded sensor data, wherein the decoding includes applying a data decompression technique to the encoded sensor data, wherein the data decompression technique is configurable by one or more decompression parameters, wherein the applying of the data decompression technique to the encoded sensor data includes selecting at least one of the one or more decompression parameters based on the one or more attributes of the object.

14. A non-transitory computer-readable medium including data representing instructions encoding sensor data for transmission to a receiver, the instructions, when executed by a processor system, causing the processor system to perform the following steps:
obtaining sensor data acquired by a sensor;
applying an object detection technique to the sensor data to detect an object in the sensor data and to determine one or more attributes of the object;
encoding the sensor data to obtain encoded sensor data, wherein the encoding includes applying a data compression technique to the sensor data, wherein the data compression technique is configurable by one or more compression parameters, wherein the applying of the data compression technique to the sensor data includes selecting at least one of the one or more compression parameters based on the one or more attributes of the object;
generating object data indicative of the one or more attributes of the object; and
sending the encoded sensor data and the object data to the receiver to enable the receiver to select one or more decompression parameters of a data decompression technique based on the one or more attributes of the object.

15. A sender device, comprising:
a processor subsystem;
a sensor interface to a sensor; and
a communication interface to a receiver device;
wherein the sender device is configured to encode sensor data for transmission to the receiver device, the sensor device configured to:
obtain sensor data acquired by the sensor,
apply an object detection technique to the sensor data to detect an object in the sensor data and to determine one or more attributes of the object,
encode the sensor data to obtain encoded sensor data, wherein the encoding includes applying a data compression technique to the sensor data, wherein the data compression technique is configurable by one or more compression parameters, wherein the applying of the data compression technique to the sensor data includes selecting at least one of the one or more compression parameters based on the one or more attributes of the object,
generate object data indicative of the one or more attributes of the object,
send the encoded sensor data and the object data to the receiver device to enable the receiver device to select one or more decompression parameters of a data decompression technique based on the one or more attributes of the object.

16. A receiver device, comprising:
a processor subsystem; and
a communication interface to a sender device;
wherein the receiver device is configured to decode sensor data received from the sender device, the receiver configured to:
receive encoded sensor data from the sender device,
receive object data from the sender device, wherein the object data is indicative of one or more attributes of an object which is detectable in the sensor data, and
decode the encoded sensor data to obtain decoded sensor data, wherein the decoding includes applying a data decompression technique to the encoded sensor data, wherein the data decompression technique is configurable by one or more decompression parameters, wherein the applying of the data decompression technique to the encoded sensor data includes selecting at least one of the one or more decompression parameters based on the one or more attributes of the object.

17. A distributed sensor network, comprising:
a sender device including:
a processor subsystem;
a sensor interface to a sensor; and
a communication interface to a receiver device;
wherein the sender device is configured to encode sensor data for transmission to the receiver device, the sensor device configured to:
obtain sensor data acquired by the sensor,
apply an object detection technique to the sensor data to detect an object in the sensor data and to determine one or more attributes of the object,
encode the sensor data to obtain encoded sensor data, wherein the encoding includes applying a data compression technique to the sensor data, wherein the data compression technique is configurable by one or more compression parameters, wherein the applying of the data compression technique to the sensor data includes selecting at least one of the one or more compression parameters based on the one or more attributes of the object,
generate object data indicative of the one or more attributes of the object,
send the encoded sensor data and the object data to the receiver device to enable the receiver device to select one or more decompression parameters of a data decompression technique based on the one or more attributes of the object; and
the receiving device, including:
a processor subsystem; and
a communication interface to the sender device;
wherein the receiver device is configured to decode sensor data received from the sender device, the receiver configured to:
receive encoded sensor data from the sender device,
receive object data from the sender device, wherein the object data is indicative of one or more attributes of an object which is detectable in the sensor data, and
decode the encoded sensor data to obtain decoded sensor data, wherein the decoding includes applying a data decompression technique to the encoded sensor data, wherein the data decompression technique is configurable by one or more decompression parameters, wherein the applying of the data decompression technique to the encoded sensor data includes selecting at least one of the one or more decompression parameters based on the one or more attributes of the object;
wherein the sender device is a sensor device and the receiver device is a sensor data processing device.
